(19) United States
(12) Patent Application Publication
(10) Pub. No.: US 2026/0164692 A1
(43) Pub. Date: Jun. 11, 2026

(54) MANUFACTURING PROCESS FOR VERTICAL GaN-BASED TRANSISTORS

(71) Applicant: COMMISSARIAT A L'ENERGIE ATOMIQUE ET AUX ENERGIES ALTERNATIVES, Paris (FR)

(72) Inventors: Julien BUCKLEY, Grenoble Cedex 09 (FR); Matthew CHARLES, Grenoble Cedex 09 (FR); Jérôme BISCARRAT, Grenoble Cedex 09 (FR); Thomas KALTSOUNIS, Grenoble Cedex 09 (FR); Philippe GODIGNON, Grenoble Cedex 09 (FR); Mohammed EL AMRANI, Grenoble Cedex 09 (FR); David PLAZA ARGUELLO, Grenoble Cedex 09 (FR); Hala EL RAMMOUZ, Grenoble Cedex 09 (FR); Vishwajeet MAURYA, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/358,741

(22) Filed: Oct. 15, 2025

(30) Foreign Application Priority Data
Oct. 16, 2024 (FR) FR2411188

(51) Int. Cl. H10D 30/01; H10D 30/63; H10D 62/85

(52) U.S. Cl. CPC H10D 30/025; H10D 30/63; H10D 62/8503

(57) ABSTRACT

A method for manufacturing at least one vertical transistor First, a substrate is provided, having an upper face, a localized epitaxy of GaN is performed on the substrate, so as to form at least one island, and, at each island, at least one electrically conductive pattern called a gate and at least one electrically conductive contact called a source contact are formed. The substrate is removed, and an electrically conductive layer forming a drain is formed against the lower face of the at least one island, thus forming at least one vertical transistor.

### TECHNICAL FIELD

The present invention relates to the field of microelectronic devices, in particular, GaN-based components. It has, for example, a particularly advantageous application in the field of power electronics.

### PRIOR ART

There are numerous transistor architectures, among which, vertical transistors. The properties of these transistors are, today, particularly utilised in power electronics applications.

GaN-based vertical transistors are typically manufactured by epitaxy from GaN substrates. However, GaN substrates available in the industry are of a low diameter. The current methods for manufacturing GaN vertical transistors on a GaN substrate do not therefore make it possible to simultaneously manufacture a quantity of transistors comparable to what is produced on substrate with a larger diameter (silicon substrates, typically). These methods are moreover very expensive, due to the high price of GaN substrates.

An aim of the present invention is thus to propose a method for manufacturing GaN-based vertical transistors, resolving at least some of the problems stated above.

### SUMMARY

To achieve this aim, according to an embodiment, a method for manufacturing at least one vertical transistor is provided, comprising the following steps:
providing a substrate having an upper face, typically a silicon substrate,
performing a localised gallium nitride (GaN) epitaxy on the upper face of the substrate, so as to form at least one GaN-based island, each island comprising a first GaN-based layer doped with a first type taken from among an n-type doping and a p-type doping, and a second GaN-based layer doped with the other type, directly surmounting the first layer, each island having a face, called lower, rotated facing the upper face of the substrate,
at each island, forming at least one gate in contact with the first layer and with the second layer, the at least one gate comprising an electrically conductive pattern, and forming at least one electrically conductive contact called source contact in contact with the second layer,
forming an electrically conductive layer forming a drain, the drain being electrically connected to the lower face of each island, thus forming at least one vertical transistor.

Thus, the method according to the invention makes it possible to initiate the formation of transistors on a large substrate and inexpensive, such as a silicon substrate. Thus, having to resort to an expensive and small GaN substrate is avoided. The steps of forming gates and source contacts can be carried out, while the islands rest on the substrate, or after removal of this substrate. The formation of the drain in the rear face simply requires to remove the substrate by grinding and/or CMP and/or etching beforehand, or to make metal interconnections in the substrate, which is absolutely reasonable in the case of a silicon substrate. Thus, fully vertical GaN transistors are obtained, without having to sacrifice a GaN substrate.

The local epitaxy of GaN can further make it possible to form islands of a height going up to 10 μm, even 20 μm. Thanks to this, the transistors formed by the method can support voltages as high as 1200V, even 2200V.

Moreover, the method makes it possible to effectively manufacture vertical transistors with a very high substrate coverage rate. For hexagonal substrates, for example, the surface lost due to gaps between islands is between 5 to 10% of the total surface, which is very low.

Thus, the method according to the invention enables an effective, large-scale and inexpensive manufacture of GaN-based vertical transistors. The manufactured transistors are moreover very compact and robust.

### BRIEF DESCRIPTION OF THE FIGURES

The aims, objectives, as well as the features and advantages of the invention will best emerge from the detailed description of an embodiment of the latter, which is illustrated by the following accompanying drawings, in which:

FIGS. 1A to 1F illustrate a first embodiment of the method according to the invention, in which the transistor gates are formed in the GaN islands.

FIGS. 1E and 1F illustrate an example, in which the substrate is removed and the drain is formed in direct contact with the islands.

FIGS. 1G and 1H illustrate an example, in which metal interconnections are formed in the substrate and the drain is formed in contact with these interconnexions.

FIGS. 2A to 2F illustrate a second embodiment of the method according to the invention, in which the transistor gates are formed in the GaN islands.

FIGS. 3A to 3D illustrate a third embodiment of the method according to the invention, in which the transistor gates are formed against the GaN islands.

FIGS. 4A to 4C are images obtained by scanning electron microscopy (SEM) of crude GaN islands by localised epitaxy.

FIG. 4B is a magnification of FIG. 4A.

FIG. 4C is a magnification of FIG. 4B.

The drawings are given as examples, and are not limiting of the invention. They constitute principle schematic representations, intended to facilitate the understanding of the invention, and are not necessarily to the scale of practical applications. In particular, the dimensions are not representative of reality.

### DETAILED DESCRIPTION

Before starting a detailed review of embodiments of the invention, optional features are stated below, which can optionally be used in association or alternatively:

According to an advantageous example, the substrate is silicon-based. Silicon substrate are indeed inexpensive, and are very well suited to performing localised GaN epitaxies.

According to a preferred example, each island has a height h₁₀₀ greater than or equal to 10 μm, preferably greater than or equal to 20 μm, h₁₀₀ being measured in a direction perpendicular to a plane into which the upper face of the substrate mainly extends.

According to an embodiment, the step of forming the drain comprises the following steps:
after formation of the at least one island, removing the substrate, then
forming the drain against the lower face of the at least one island.

According to an embodiment, the step of forming the drain comprises the following steps:
for each island, forming at least one metal interconnection passing through the substrate and opening onto said island,
forming the drain against a lower face of the substrate opposite its upper face, the drain being in contact with the at least one metal interconnection.

According to an advantageously embodiment, the formation of the at least one gate comprises the following steps:
etching at least one opening extending from the upper face of the at least one island, the opening fully passing through the second layer and passing through the first layer, at least partially,
forming the at least one gate in the at least one opening.

Due to the positioning of the gate (or the gates) at the upper face of the islands, this embodiment enables a high transistor density.

According to an advantageous embodiment, the epitaxy step comprises the following step: forming, by epitaxy, the first layer and the second layer through a mask, so as to define at least one opening extending from an upper face of the at least one island, the opening passing through the second layer and passing through the first layer at least partially, and the at least one gate is formed in said at least one opening. This embodiment does not require the performing of an etching in the GaN island(s) to form the gate(s), which avoids the introduction of charges in the islands. These charges are indeed damaging to the correct operation of the transistors, as they can cause a hysteresis during a switching. Due to the positioning of the gate (or the gates) at the upper face of the islands, this embodiment moreover enables a high transistor density.

According to a preferred example, a plurality of gates is formed in contact with the first layer and with the second layer of one same island. The presence of a plurality of gates makes it possible to increase the power of the formed transistor.

According to a preferred example, a plurality of source contacts is formed in contact with the second layer and, projecting into a plane in which the upper face of the substrate mainly extends, the gates and the source contacts alternate.

According to an advantageous embodiment, at least two islands and two transistors are formed, and the gate formed at the first island, and that formed at the second island are in electrical continuity and form a gate common to the two transistors.

According to an example, the gate common to the two transistors extends between a lateral flank of the first island and a lateral flank of the second island. This embodiment does not require the performing of an etching in the GaN island(s) to form the gate(s), which avoids the introduction of charges in the islands. These charges are indeed damaging to the correct functioning of the transistors, as they can cause a hysteresis during a switching.

According to an example, the drain is copper-based. The properties of copper indeed make it possible to give the transistor(s) optimal thermal and electrical performance.

According to an advantageous example, the step of removing the substrate is carried out before the formation of the gate and of the at least one source contact at each island, and optionally before the formation of the first layer and of the second layer. The removal of the substrate at the start of the method makes it possible to decrease the stress in the different layers and, in particular, in the GaN islands during the method. This makes it possible to limit the quantity of structural defects in the stack, and therefore to improve the performance of the transistors.

According to an alternative example, the step of removing the substrate is carried out after the formation of the gate and of the at least one source contact at each island.

It is specified that, in the scope of the present invention, the terms “on”, “surmounts”, “covers”, “underlying”, “opposite” and their equivalents do not necessarily mean “in contact with”. Thus, for example, the deposition, the transfer, the bonding, the assembly or the application of a first layer on a second layer, does not compulsorily mean that the two layers are directly in contact with one another, but means that the first layer at least partially covers the second layer by being, either directly in contact with it, or by being separated from it by at least one other layer or at least one other element.

A layer can moreover be composed of several sublayers of one same material or of different materials.

By a substrate, a layer, a device “with the basis” of a material M, this means a substrate, a layer, a device comprising this material M only, or this material M and optionally other materials, for example, alloy elements, impurities or doping elements.

By “selective etching with respect to” or “etching having a selectivity with respect to” an etching configured to remove a material A or a layer A with respect to a material B or a layer B, and having an etching speed of the material A greater than the etching speed of the material B. The selectivity is the ratio between the etching speed of the material A over the etching speed of the material B. The selectivity between A and B is referenced SA:B.

Two elements are called “electrically connected” when they are each in contact with one same continuous electrical connection element having an electrical conduction preferably greater than 10⁷ S/m.

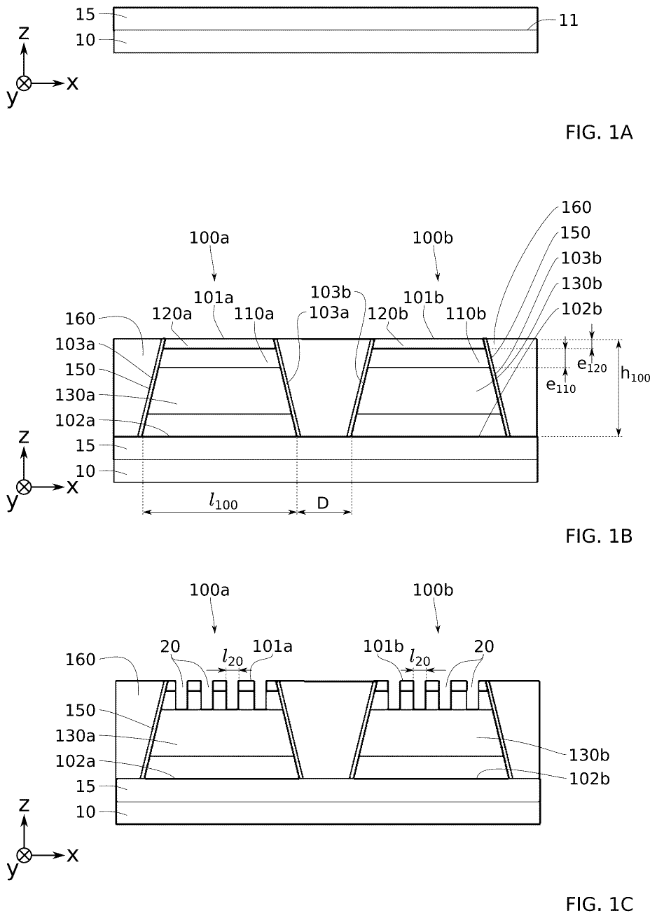

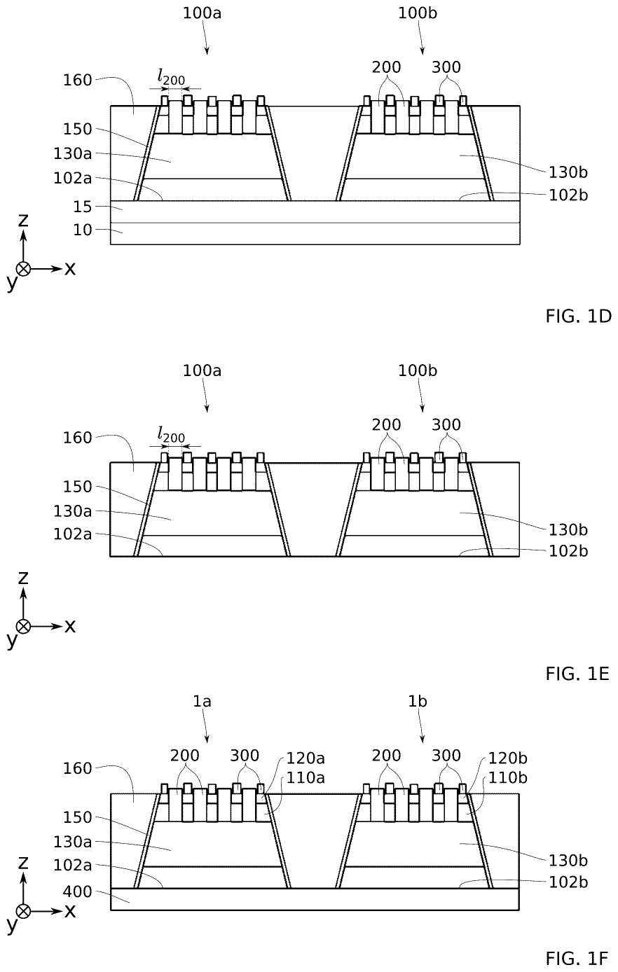

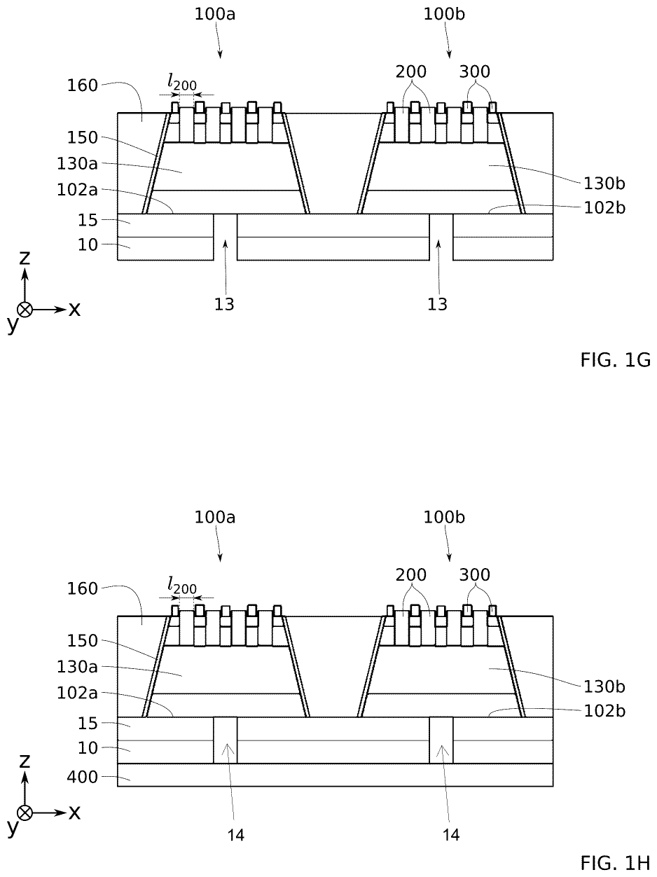

A preferably orthonormal system, comprising the axes X, Y, Z is represented in FIG. 1A. This system is applicable by extension to the other figures. The direction Z can be called “stacking direction”.

In the present patent application, thickness will preferably be referred to for a layer, and height will preferably be referred to for a structure or a device. The height is taken perpendicularly to the longitudinal plane XY. The thickness is taken along a direction normal to the main extension plane of the layer. Thus, a layer typically has a thickness along Z, when it extends mainly along the longitudinal plane XY, and a projecting element, for example, an insulation trench, has a height along Z. The relative terms “on”, “under”, “above” “below”, “underlying” preferably refer to positions taken along the direction Z.

The terms “substantially”, “around”, “about” mean “plus or minus 10%, preferably plus or minus 5%”.

A first embodiment of the method according to the invention will now be described in reference to FIGS. 1A to 1F. These figures illustrate the simultaneous formation of two transistors 1a, 1b, but it is understood that a larger number of transistors can be manufactured simultaneously by the method according to the invention.

FIG. 1A illustrates the provision of a substrate 10. This substrate 10 is typically silicon-based. It has an upper face 11 extending mainly in a plane XY being able to be called longitudinal plane XY. This plane is defined by a first direction X and a second direction Y. The substrate 10 further has a lower face 12 opposite its upper face 11.

Advantageously, buffer layers 15 are deposited on the upper face 11 of the substrate 10. These buffer layers 15 can, for example, each be with the basis of one of the following materials: AlN, AlGaN, BN.

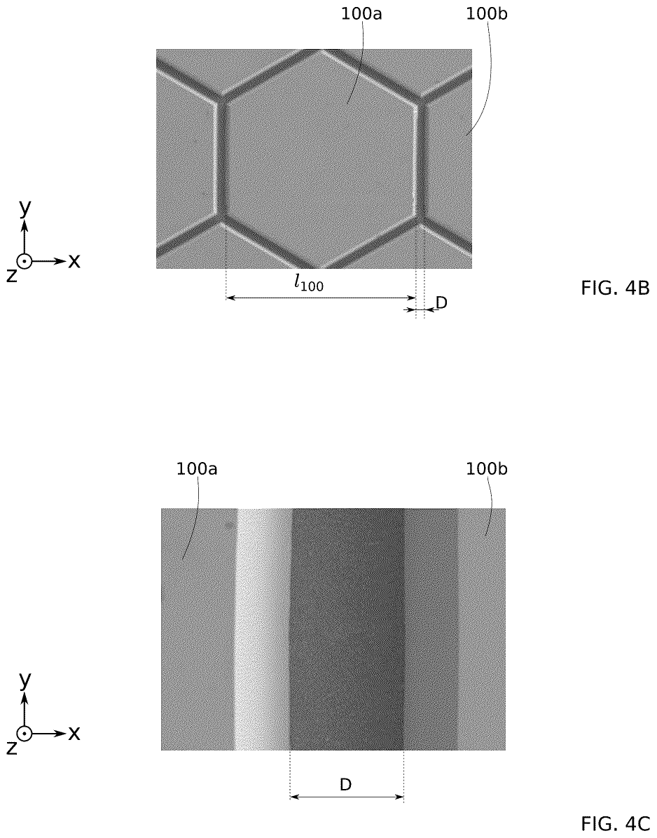

As illustrated in FIG. 1B, GaN-based islands 100a, 100b are then locally crude by epitaxy on the upper face 11 of the substrate 10. Typically, these islands 100a, 100b are crude from the buffer layers 15. FIG. 4A illustrates the experimental result of this step: it constitutes a top view obtained by SEM of a set of islands crude by localised epitaxy on a silicon substrate. It can, in particular, be assessed on this image, that a large number of islands can be simultaneously crude by localised epitaxy.

The islands 100a, 100b are separated from one another. Thus, preferably, no residual, continuous GaN layer is found on the upper face 11 of the substrate 10 (except for optional buffer layers being able to comprise GaN).

The islands 100a, 100b each have a lower face 102a, 102b located facing the upper face 11 of the substrate 10, and typically in contact with the buffer layers 15. Moreover, they each have an upper face 101a, 101b opposite the lower face 102a, 102b.

The step of epitaxially growing the GaN islands 100a, 100b is advantageously configured to form GaN layers within each island 100a, 100b having different dopings. According to an advantageous example, the islands 100a, 100b comprise following layers, from the lower faces 102a, 102b of the islands 100a, 100b to their upper faces 101a, 101b: an n+-doped GaN layer, an n−-doped GaN layer, being able to be called a drift layer 130a, 130b, a p-doped GaN layer, called first layer 110a, 110b, and an n+-doped GaN layer, called second layer 120a, 120b. According to an alternative example, the dopings of the layers are inverted and the first layer 110a, 110b is n+-doped and the second layer 120a, 120b is p-doped.

Fully conventionally, the doping of the n-doped layers can be silicon (Si) and the doping of the p-doped layers can be magnesium (Mg).

The islands 100a, 100b have a characteristic dimension in the plane XY referenced I₁₀₀. Projecting into the plane XY, the islands 100a, 100b typically each have a hexagonal shape, as can be observed in FIG. 4A. In this case, the characteristic dimension I₁₀₀ corresponds to the distance between two flanks of the island 100a, 100b facing one another. In FIG. 4B, I₁₀₀ is, for example, measured along the first direction X. I₁₀₀ is preferably greater than 100 μm, and preferably less than or equal to 200 μm.

The lateral flanks 103a, 103b of the islands 100a, 100b are typically inclined with respect to the stacking direction Z, as illustrated in the figures. I₁₀₀ is thus measured at the base of the islands 100a, 100b, at their lower face 102a, 102b.

The islands 100a, 100b have a height h₁₀₀ measured along the direction Z (also called stacking direction Z) perpendicular to the longitudinal plane XY. The height h₁₀₀ is preferably greater than 10 μm even 20 μm. Moreover, the first layer 110a, 110b and the second layer 120a, 120b respectively have a thickness e₁₁₀ and a thickness e₁₂₀ along the stacking direction Z. Typically, e₁₁₀ is between 200 nm and 1500 nm. Typically, e₁₂₀ is between 20 nm and 300 nm.

In the longitudinal plane XY, the islands 100a, 100b are separated by a distance D (taken along the first direction X in FIGS. 1B, 4B and 4C). D is measured at the foot of the islands 100a, 100b, i.e. at the height along Z at which the lower faces 102a, 102b of the islands 100a, 100b are located. The distance D is typically greater than 5 μm. The distance D is preferably less than 20 μm even less than 15 μm, even 10 μm. D is typically between 10 and 15 μm. This makes it possible to manufacture transistors with a better density. It is, for example, substantially equal to 8 μm.

The numerical values given above are also valid for the second and third embodiments, which will be described further.

As is also illustrated in FIG. 1B, the lateral flanks 103a, 103b of the islands 100a, 100b are advantageously covered with a passivation layer 150. The passivation layer 150 is, for example, alumina-or SIN-based.

The spaces left empty between the islands 100a, 100b are preferably filled by a filling layer 160 with the basis of a dielectric material, for example, silica-or tetraethyl orthosilicate (TEOS)-based. The deposition of the filling layer 160 can be done by sub-atomical chemical vapour deposition (SACVD). Advantageously, this deposition is done according to a low stress method.

The deposition of the filling layer 160 can be followed by a planarisation step at the upper face 101a, 101b of the islands 100a, 100b.

An etching step is then carried out from the upper faces 101a, 101b of the islands 100a, 100b. This etching step is configured to form at least one opening 20, and preferably, a plurality of openings 20, in each islands 100a, 100b. Each opening 20 fully passes through the second layer 120a, 120b and at least partially, preferably fully, the first layer 110a, 110b. As will appear further, the dimensions of the openings 20 condition those of the gates 200 of the transistors 1a, 1b. The openings 20 have, for example a width I₂₀ along the first direction X, with I₂₀ between 100 nm and 4000 nm. According to the second direction Y, the openings 20 can fully pass through the islands 100a, 100b. According to an alternative embodiment, the openings 20 have, projecting into the transverse plane XY, a hexagonal shape. I₂₀ thus typically corresponds to one side of the hexagon.

Fully conventionally, this etching step can be carried out by dry etching through a masking layer.

During a step illustrated in FIG. 1D, electrically conductive patterns 200 are formed in the openings 20. These electrically conductive patterns form part of the gates 200 of the transistors which will be formed at the end of the method. The width I₂₀₀ of the gates 200 is substantially equal to the width I₂₀ of the openings 20. It is understood that each gate 200 can also comprise a semiconductor oxide (for example, SiO₂), called gate oxide or gate dielectric. The gate oxide is in contact with the electrically conductive pattern. The gate oxides are typically formed at this same step.

Moreover, electrically conductive contacts called source contacts 300 are also formed on the second layer 120a, 120b.

As illustrated in FIG. 1E, the removal of the substrate 10 and of the optional buffer layers 15 are then proceeded with. This removal is typically done by grinding and chemical-mechanical polishing (CMP). Advantageously, a major part of the removal is done by grinding and CMP, then is finalised by selective etching or etching at the time to stop precisely on the lower face 102a, 102b of the islands 100a, 100b.

Advantageously, the removal of the substrate 10 and of the buffer layers 15 occurs after the transfer of the islands 100a, 100b onto a handle substrate (not represented). This transfer occurs on the side of the upper face 101a, 101b of the islands 100a, 100b. The handle substrate is removed after the formation of the drain 400 described further.

The removal of the substrate 10 and of the buffer layers 15 can also occur earlier in the method. The substrate 10 can indeed be removed after the formation of the islands 100a, 100b (and the optional formations of the passivation layer 150 and of the filling layer 160), and before the formation of the gates 200 and source contacts 300, between the steps illustrated in FIGS. 1B and 1C or 1C and 1D. This makes it possible to reduce the mechanical stresses within the stack during the formation of the gates 200 and of the source contacts 300.

After the formation of the gates 200 and of the source contacts 300, the formation of an electrically conductive layer called drain 400 in contact with the lower faces 102a, 102b of the islands 100a, 100b is proceeded with. This drain 400 extends continuously under the islands 100a, 100b. It is thus common to all the transistors 1a, 1b. The formation of the drain 400 is typically done by electrochemical metal deposition.

According to an alternative embodiment illustrated in FIGS. 1G and 1H, rather than removing the substrate 10 and the buffer layers 15, metal interconnections are made. Thus, it is possible, as illustrated in FIG. 1G, to make through openings 13 fully passing through the substrate 10 and optionally the buffer layers 15 by etching. The through openings 13 thus extend, in particular, from the upper face 11 to the lower face 12 of the support. At least one through opening 13 is formed, facing each island 100a, 100b. The through openings 13 are typically formed by a photolithography and etching method. The through openings 13 are then filled with an electrically conductive material, typically a metal, so as to form metal interconnections 14 also passing through the substrate 10 and the buffer layers 15. The drain 400 is thus against the lower face 12 of the substrate 10 (FIG. 1H). The drain 400 is formed in contact with at least one metal interconnection 14, preferably with all the metal interconnections 14. The metal interconnections 14 ensure the electrical connection between the drain 400 and the islands 100a, 100b.

The method thus makes it possible to form at least one transistor 1a, 1b, each formed from the following elements:
The drain 400, or the at least one portion of this drain 400,
An island 100a, 100b, comprising GaN layers with distinct dopings, including the first layer 110a, 110b and the second layer 120a, 120b,
At least one gate 200 deposited in contact with the first layer 110a, 110b and with the second layer 120a, 120b of the island 100a, 100b considered,
At least one source contact 300 deposited on the second layer 120.

The different steps of the method (formation of the openings 20 in the islands 100a, 100b, formation of the gates 200, formation of the source contacts 300) are preferably such that projecting in the longitudinal plane XY, the gates 200 and the source contacts 300 alternate. Typically, each formed transistor 1a, 1b comprises a source contact 300 in addition to gates 200.

The presence of a plurality of gates 200 and of source contacts 300 within each transistor 1a, 1b makes it possible to increase their power. Advantageously, each transistor 1a, 1b comprises at least 3 gates 200, preferably at least 5 gates 200.

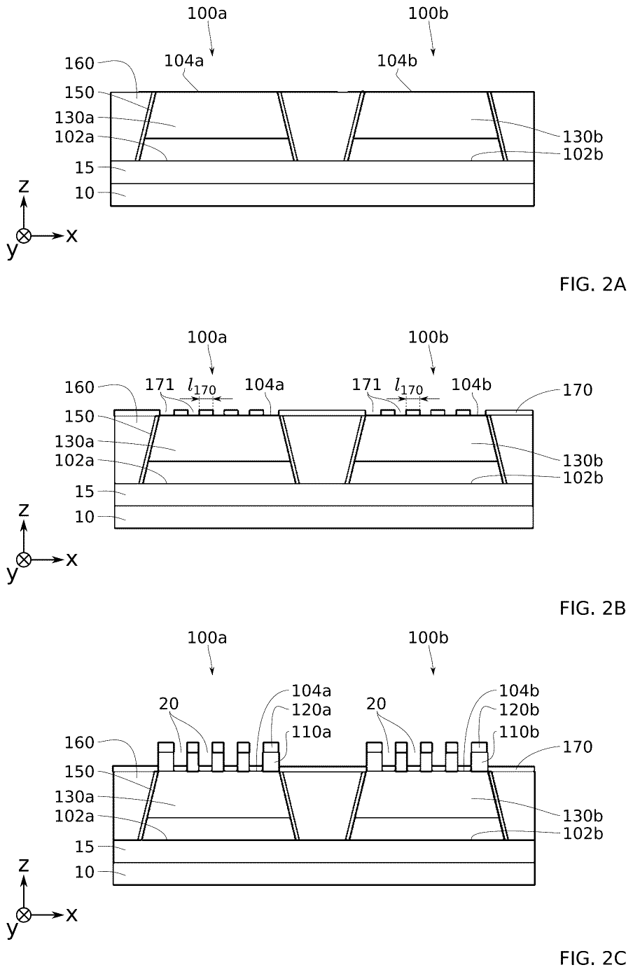

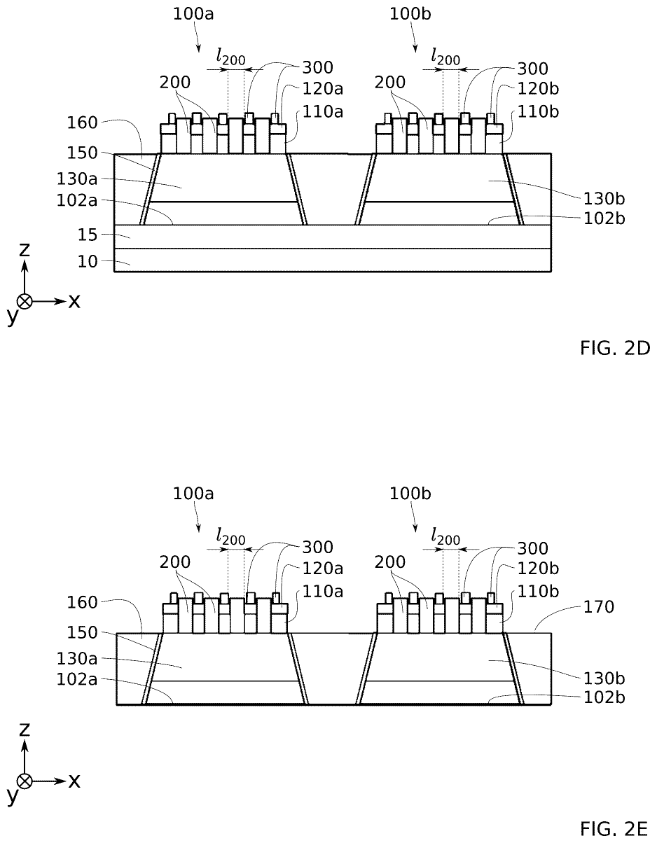

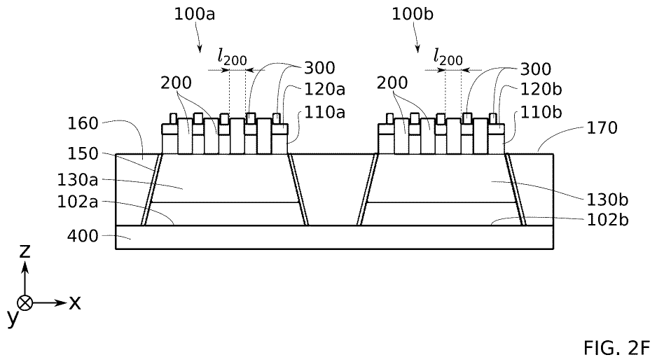

A second embodiment will now be described in reference to FIGS. 2A to 2F.

The second embodiment can, for example, start like the first embodiment described above with the provision of a substrate 10 and advantageously of buffer layers 15, as illustrated in FIG. 1A.

Then, the epitaxy of the islands 100a, 100b is started above the upper face 11 of the substrate 10, but it is interrupted before the formation of the first layer 110a, 110b and of the second layer 120a, 120b, as illustrated in FIG. 2B. At this stage, the islands 100a, 100b each have an intermediate face 104a, 104b opposite their lower faces 102a, 102b.

A hard mask 170 is then formed on the intermediate faces 104a, 104b of the islands 100a, 100b. The hard mask 170 has at least one opening 171, and preferably a plurality of openings 171, partially revealing the intermediate faces 104a, 104b of the islands 100a, 100b. As will appear further, the dimensions of the pattern defined by mask 170 condition the dimensions of the gates 200 of the transistors 1a, 1b. The mask 170 can, for example, comprise bands extending between the openings 171. These mask bands 170 have a width I₁₇₀ along the first direction X, with preferably, I₁₇₀ of between 100 nm and 4000 nm. The mask 170 can also comprise openings having a hexagonal shape. The characteristic dimension I₁₇₀ of these openings thus corresponds to the side of the hexagon.

As illustrated in FIG. 2C, the first layer 110a, 110b and the second layer 120a, 120b are then formed by epitaxy from the intermediate face 104a, 104b, through the openings 171 of the mask 170.

Preferably, during this epitaxy step, the formation of the first layer 110a, 110b is preceded by an n-GaN growth. This n-GaN layer preferably has a thickness at least equal to that of the gate dielectric.

According to an advantageous embodiment, the mask 170 is preserved after the epitaxy step. This enables an additional thickness at the bottom of the gate which is favourable to the holding of the electric field of the gate when the component is blocked. In this case, advantageously, the thickness of the n-GaN layer is equal to the sum of the thickness of the gate dielectric and of that of the mask 170.

In this embodiment, the first layer 110a, 110b and the second layer 120a, 120b are thus directly formed with the openings 20, conversely from the first embodiment, where these are formed by etching in the first layer 110a, 110b and in the second layer 120a, 120b. The openings 20 are defined in this second embodiment by the mask 170.

The mask 170 is then removed, as the passage from FIG. 2C to FIG. 2D illustrates.

The gates 200 and source contacts 300 are then formed respectively in the openings 20 and on the second layer 120a, 120b such as described above in the scope of the first embodiment (FIG. 2D).

The steps of removing the substrate 10 (FIG. 2E) and of forming the drain 400 (FIG. 2F) are themselves also carried out similarly to what has been described in reference to the first embodiment. Just like in the first embodiment, it is also possible to perform metal interconnections in the substrate 10 and in the buffer layers 15 and to form the drain in contact with the lower face 12 of the substrate 10.

The method thus makes it possible to form at least one transistor 1a, 1b, each formed from the following elements:
The drain 400, or the at least one portion of this drain 400,
An island 100a, 100b, comprising GaN layers with distinct dopings including the first layer 110a, 110b and the second layer 120a, 120b,
At least one gate 200 deposited in contact with the first layer 110a, 110b and with the second layer 120a, 120b of the island 100a, 100b considered,
At least one source contact 300 deposited on the second layer 120.

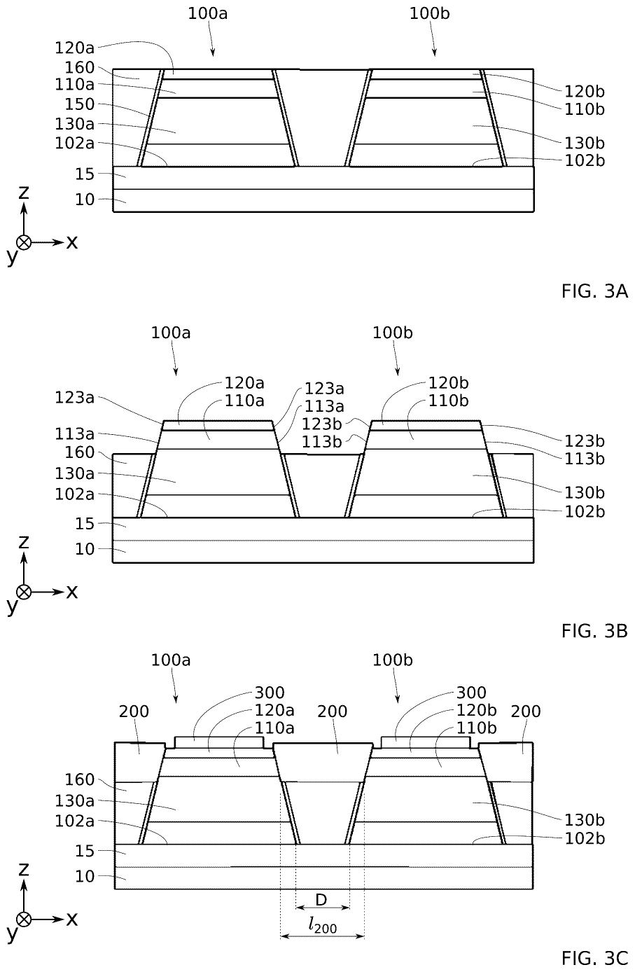

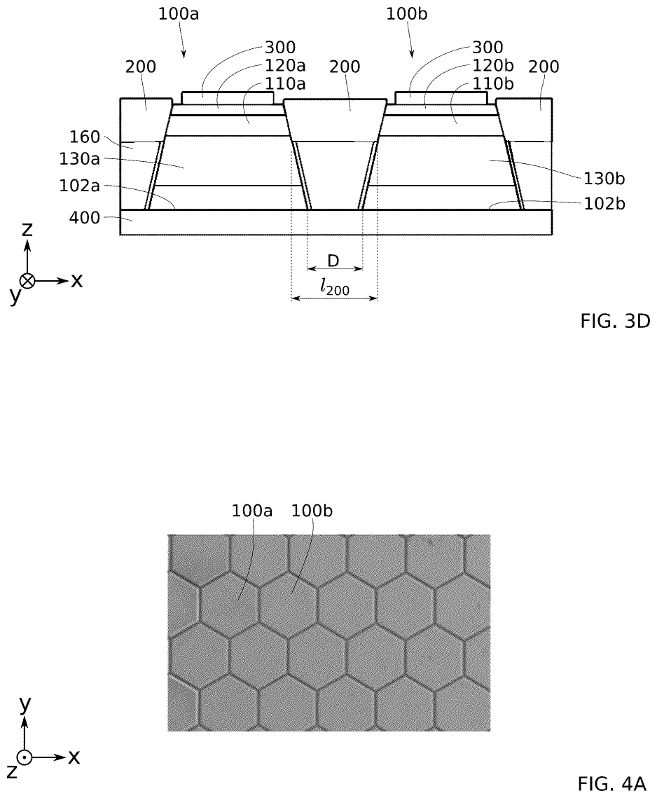

A third embodiment will now be described in reference to FIGS. 3A to 3D.

Just like the first embodiment of the method, this embodiment can, for example, start with the provision of a substrate 10 and the formation by localised epitaxy of islands 100a, 100b (FIG. 1A then 1B corresponding to FIG. 3A).

The spaces between islands 100a, 100b are also filled with a filling dielectric layer 160 (FIG. 3A).

As illustrated in FIGS. 3A and 3B, the filling layer 160 can first be formed up to the height of the upper faces 101a, 101b of the islands 100a, 100b (FIG. 3A) then be etched, such that the filling layer 160 is removed along the direction Z with respect to the first layer 110a, 110b and to the second layer 120a, 120b (FIG. 3B).

According to another example, the filling layer 160 is selectively etched, such that it is removed along the direction Z with respect to the first layer 110a, 110b and to the second layer 120a, 120b (FIG. 3B).

In both cases, as illustrated in FIG. 3B, the external flanks 113a, 113b, 123a, 123b of the first 113a, 123a and second 113b, 123b layers are exposed.

An electrically conductive pattern or gate 200 is then deposited on the filling layer 160. The gate 200 extends from the external flanks 113a, 123a of the first and second layers 110a, 120a, of an island 100a up to the external flanks 113b, 123b of the first and second layers 110b, 120b, of the neighbouring island 100b. Thus, in this embodiment, the gate 200 is common to the two neighbouring islands 100a, 100b.

The external flanks of the islands 100a, 100b being inclined, the width of the gate 200 is typically variable along the direction Z. However, the inclination is relatively low, and the width of the gate 200 is found, in reality, to be of the same magnitude as the distance D separating the islands 100a, 100b.

By simplification, the width I₂₀₀ of the gate 200 is measured at its lower face facing, even in contact with, the filling layer 160. The width I₂₀₀ is typically greater than 198 μm, for example, 199 μm. The width I₂₀₀ is preferably less than 200 μm, even 199 μm.

A source contact 300 is then formed on the second layer 120a, 120b of each island 100a, 100b. The source contacts 300 are specific to each island 100a, 100b.

The stack illustrated in FIG. 3C is thus obtained.

The steps of removing the substrate 10 and of forming the drain 400 (FIG. 3D) are carried out similarly to what has been described in reference to the first embodiment.

The method thus makes it possible to form at least one transistor 1a, 1b, each formed from the following elements:
The drain 400, or the at least one portion of this drain 400,
An island 100a, 100b, comprising GaN layers with distinct dopings including the first layer 110a, 110b and the second layer 120a, 120b,
At least one gate 200 deposited in contact with the lateral flanks 113a, 123a of the first layer 110a, 110b and of the lateral flanks 113b, 123b of the second layer 120a, 120b of the island 100a, 100b considered,
A source contact 300 deposited on the second layer 120.

The paragraphs below aim to detail the operation of the transistors 1a, 1b obtained by the method according to the invention. These explanations are valid for all the embodiments. In particular, they are applied to each gate 200/source contact 300 in the case of multi-gate transistors such as illustrated in the first and the second embodiment.

When the gate(s) 200 are positively biased relative to the source contact(s) 300, an electron channel is formed through the first layer 110a, 110b and the second layer 120a, 120b, against the gate(s) 200. For example, in the case of the third embodiment, the electron channel is formed in the proximity, even at the external flanks 113a, 113b, 123a, 123b of these layers 110a, 110b, 120a, 120b. The electrons then pass into the drift layer 130a, 130b, the into the drain 400.

Conversely, when the gate(s) 200 are negatively biased relative to the source contact(s) 300, there is no longer an electron channel, the first layer 110a, 110b and the second layer 120a, 120b form a PN junction and the drift layer 130a, 130b is depleted.

Thus, in view of the different embodiments described above, the invention makes it possible to manufacture GaN-based vertical transistors without using a GaN substrate, expensive and often only available in low dimensions.

The invention is not limited to the embodiments described above and extends to all the embodiments covered by the invention.

1. A method for manufacturing at least one vertical transistor, comprising:
providing a substrate having an upper face,
performing a pocalized epitaxy of gallium nitride (GaN) on the upper face of the substrate, so as to form at least one GaN-based island, each island comprising a first GaN-based layer doped with a first type taken from among an n-type doping and a p-type doping, and a second GaN-based layer, of the other type directly surmounting the first layer, each island having a lower face rotated facing the upper face of the substrate,
at each island, forming at least one gate in contact with the first layer and with the second layer, the at least one gate comprising an electrically conductive pattern, and forming at least one electrically conductive source contact in contact with the second layer, and
forming an electrically conductive layer forming a drain, the drain being electrically connected to the lower face of each island, thus forming the at least one vertical transistor.

2. The manufacturing method according to claim 1, wherein the substrate is silicon-based.

3. The manufacturing method according to claim 1, wherein each island has a height greater than or equal to 10 μm, the height being measured in a direction perpendicular to a plane into which the upper face of the substrate mainly extends.

4. The manufacturing method according to claim 1, wherein the step of forming the drain comprises:
after formation of the at least one island, removing the substrate, and
forming the drain against the lower face of the at least one island.

5. The manufacturing method according to claim 1, wherein the step of forming the drain further comprises:
for each island, forming at least one metal interconnection passing through the substrate and opening onto said island,
forming the drain against a lower face of the substrate opposite the upper face, the drain being located in contact with the at least one metal interconnection.

6. The manufacturing method according to claim 1, wherein the formation of the at least one gate comprises:
etching at least one opening extending from the upper face of the at least one island, the opening fully passing through the second layer and at least partially passing through the first layer, and
forming the at least one gate in the at least one opening.

7. The manufacturing method according to claim 1, wherein the epitaxy step comprises:
forming, by epitaxy, the first layer and the second layer through a mask, so as to define at least one opening extending from an upper face of the at least one island, the opening passing through the second layer and at least partially passing through the first layer, and
wherein the at least one gate is formed in said at least one opening.

8. The manufacturing method according to claim 1, wherein a plurality of gates is formed in contact with the first layer and the second layer of one same island.

9. The manufacturing method according to claim 8, wherein a plurality of source contacts is formed in contact with the second layer, and
wherein, projecting into a plane into which the upper face of the substrate mainly extends, the gates and the source contacts alternate.

10. The manufacturing method according to claim 1, wherein at least two islands and two transistors are formed, and
wherein the gate formed at the first island and that formed at the second island are in electrical continuity and form a gate common to the two transistors.

11. The manufacturing method according to claim 10, wherein the gate common to the two transistors extends between a lateral flank of the first island and a lateral flank of the second island.

12. The manufacturing method according to claim 1, wherein the drain is copper-based.

13. The manufacturing method according to claim 4, wherein the step of removing the substrate is carried out before the formation of the gate and of the at least one source contact at each island.

14. The manufacturing method according to claim 4, wherein the step of removing the substrate is carried out after the formation of the gate and of the at least one source contact at each island.
